(19) United States
(12) Patent Application Publication
(10) Pub. No.: US 2012/0001699 A1
(43) Pub. Date: Jan. 5, 2012

(54) SYSTEM AND METHOD FOR EXTENDING VCO OUTPUT VOLTAGE SWING

(75) Inventors: Yu Yang, Beijing (CN); Xuechu Li, Beijing (CN); Rong Liu, Beijing (CN); Peiqi Xuan, Saratoga, CA (US)

(73) Assignee: QUINTIC HOLDINGS, Santa Clara, CA (US)

(21) Appl. No.: 12/872,195

(22) Filed: Aug. 31, 2010

Related U.S. Application Data
(60) Provisional application No. 61/360,501, filed on Jul. 1, 2010.

(51) Int. Cl. H03B 5/12

(52) U.S. Cl. 331/117 FE

(57) ABSTRACT

Voltage controlled oscillator (VCO) has been widely used in radio frequency communication systems. In a typical VCO implementation, a pair of directly cross-coupled MOS transistors is used as a switching device and an LC resonant circuit is used to tune the desired frequency. The direct cross coupling of the MOS transistor pair will result in limited output voltage swing since a large swing may cause the MOS transistors into a linear region to increase phase noise. The VCO system to increase the output voltage swing according to one embodiment of the present invention includes DC-blocking capacitors to avoid direct cross coupling of the MOS pair. The VCO further includes circuit to provide bias for the gate voltage of the MOS pair. A method for increasing the output voltage swing is disclosed for a VCO system having LC resonant circuit. The method includes providing DC-blocked cross coupling from the drains of the cross-coupled transistor pair to the gates of the cross-coupled transistor pair. The method also includes providing an offset voltage to the gates of the cross-coupled transistor pair to reduce the maximum gate-to-drain voltage of a cross-coupled NMOS transistor pair or maximum drain-to-gate voltage of a cross-coupled PMOS transistor pair so that the cross-coupled transistor pair will work in a saturation region when the output voltage swing is increased.

### CROSS REFERENCE TO RELATED APPLICATIONS

The present invention claims priority to U.S. Provisional Patent Application, No. 61/360,501, filed Jul. 1, 2010, entitled “System and Method for Extending VCO Output Voltage Swing.” The U.S. Provisional Patent Application is hereby incorporated by reference in its entirety.

### FIELD OF THE INVENTION

The present invention relates to voltage controlled oscillator. In particular, the present invention relates to extending the output voltage swing of a VCO having LC resonant circuit.

### BACKGROUND

Voltage controlled oscillator has been widely used in radio frequency communication systems. In a typical VCO implementation, a pair of directly cross-coupled MOS transistors is used as a switching device and an LC resonant circuit is used to tune the desired frequency. The direct cross coupling of the MOS transistor pair will result in limited output voltage swing since a large swing may cause the MOS transistors into a linear region to increase phase noise.

To overcome above issue with large VCO swing, noise filter is described in a publication by Hegazi, et al., entitled “A Filtering Technique to Lower LC Oscillator Phase Noise,” IEEE Journal of Solid-State Circuits, Vol. 36, No. 12, pp. 1921-1930, December 2001. The use of an LC noise filter helps to reduce the phase noise when the output voltage swing exceeds a limit. Nevertheless, this method needs an additional inductor, which will increase chip cost noticeably if the additional inductor is integrated on chip. Furthermore, for a wide band LC VCO, the LC noise filter resonant frequency is difficult to change with VCO frequency. Therefore, it is desirable to provide a system and method for increased output voltage swing for the VCO having LC resonant circuit.

### BRIEF SUMMARY OF THE INVENTION

The VCO system to increase the output voltage swing according to one embodiment of the present invention includes DC-blocking capacitors to avoid direct cross coupling of the MOS pair. The VCO further includes circuit to provide bias for the gate voltage of the MOS pair. In one embodiment of the present invention, complementary MOS pairs are used as switching devices of the VCO. In another embodiment of the present invention, a single type of MOS pair is used as the switching device of the VCO and the single type of MOS pair can be either a PMOS pair or an NMOS pair.

A method for increasing the output voltage swing is disclosed for a VCO system having LC resonant circuit. The method includes providing DC-blocked cross coupling from the drains of the transistor pair to the gates of the transistor pair. The method also includes providing an offset voltage to the gates of the transistor pair to reduce the maximum gate-to-drain voltage for the NMOS transistor pair or the maximum drain-to-gate voltage for the PMOS transistors so that the transistor pair will work in the saturation region.

### BRIEF DESCRIPTION OF THE DRAWINGS

FIG. 1 illustrates a conventional differential VCO circuit having an LC resonant circuit and complementary cross-coupled PMOS and NMOS transistor pairs.

FIG. 2 illustrates the V_{D} and V_{G} voltage waveform corresponding to the NMOS transistors of FIG. 1.

FIG. 3 illustrates a differential VCO circuit having an LC resonant circuit and complementary cross-coupled PMOS and NMOS transistor pairs according to an embodiment of the present invention.

FIG. 4A illustrates the output voltage waveforms at V_{O}+ and V_{O}− of FIG. 3.

FIG. 4B illustrates the V_{D} and V_{G} voltage waveforms corresponding to the NMOS transistors of FIG. 3.

FIG. 4C illustrates the V_{D} and V_{G} voltage waveforms corresponding to the PMOS transistors of FIG. 3.

FIG. 5 illustrates an alternative differential VCO circuit having an LC resonant circuit and cross-coupled NMOS-only transistor pair according to an embodiment of the present invention.

FIG. 6 illustrates an alternative differential VCO circuit having an LC resonant circuit and cross-coupled PMOS-only transistor pair according to an embodiment of the present invention.

### DETAILED DESCRIPTION OF THE INVENTION

In radio frequency (RF) systems, the local oscillator (LO) phase noise degrades the received SNR by a process known as reciprocal mixing. Voltage controlled oscillator (VCO) having LC resonant circuit is often used to generate the desired LO frequency. Such VCO determines the LO high frequency, i.e., the higher end of the PLL loop band width, phase noise. The phase noise of the VCO having an LC resonant circuit is usually characterized by Leeson's proportionality, published D. B. Leeson, entitled “A Simple Model of Feedback Oscillator Noise Spectrum,” in Proceedings IEEE, Vol. 54, pp. 329-330, February 1966:

$$L ( {w}_{m} ) ∝ \frac{1}{{V}^{2}} \cdot \frac{kT}{C} \cdot \frac{{w}_{0}}{Q} \cdot \frac{1}{{w}_{m}^{2}} , \qquad ( 1 )$$

where V is the VCO output-voltage swing. In the above equation, phase noise is proportional to the thermal noise kT/C and is shaped in frequency by the LC tank and normalized to the power in the oscillation amplitude. Furthermore, w₀ is the center frequency, wₘ is an offset frequency, and Q is the Q value of the LC circuit.

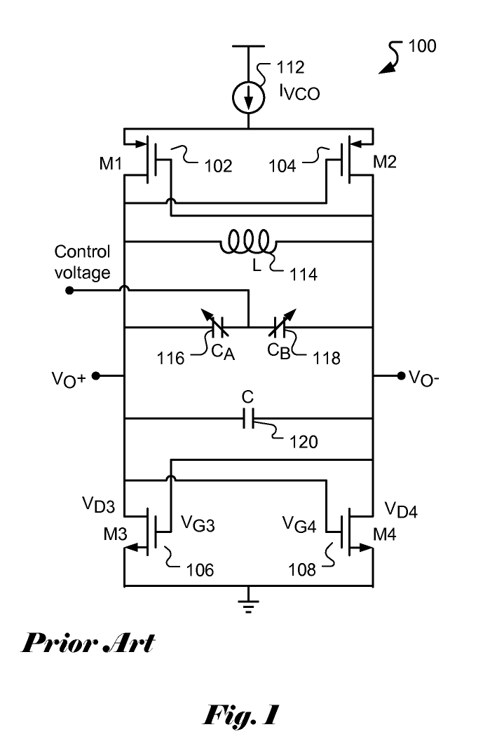

FIG. 1 illustrates a conventional VCO circuit having LC resonant circuit 100. The VCO comprises a pair of NMOS transistors M3 106 and M4 108. The LC resonant circuit comprises an inductor L 114, a fixed capacitor C 120, and a pair of adjustable capacitors C_{A} 116 and C_{B} 118. A control voltage can be supplied to the node connecting both to adjust the capacitance value. The VCO circuit shown in FIG. 1 is popular because both the NMOS (M3 106 and M4 108) and PMOS (M1 102 and M2 104) cross-coupled pairs provide negative resistance, thus the oscillation amplitude can be increased to improve the phase noise while consuming the same current consumption. On the other hand both NMOS-only and PMOS-only VCO topologies are also being used in the field to save cost. The adjustable capacitors C_{A} 116 and C_{B} 118 may be implemented based on MOS varactor technology so that the adjust capacitors can be integrated with other VCO circuitry on the same substrate. While the source terminals of NMOS transistors M3 106 and M4 108 are directly connected to ground, the two terminals can be connected to a current source as well. The capacitor C 120 can also be implemented using a switched capacitor array (SCA) to provide a wide range of tuning The SCA may be digitally controlled by individually supplying a control signal to connect or disconnect a respective capacitor from the SCA. In practice, the digitally controlled SCA is often used to provide coarse tuning while the control voltage is used to adjust the MOS varactors C_{A} 116 and C_{B} 118 for fine tuning. The use of SCA and/or MOS varactors as part of the LC resonant circuit is for the purpose of illustration and it shall not be construed as limitations to the present invention.

The VCO circuit of FIG. 1 will produce steady-state oscillation when the circuit is operated correctly. The oscillator topology forces the gate-to-drain voltage V_{GD} of the two NMOS transistors M3 106 and M4 108 to be equal in magnitude but with opposite signs. As shown in FIG. 1, the positive end of the differential voltage, V_{O}+ is connected to the drain of transistor M3 106 as well as the gate of transistor M4 108. Similarly, the negative end of the differential voltage, V_{O}− is connected to the drain of transistor M4 108 as well as the gate of transistor M3 106. The differential voltage outputs, V_{O}+ and V_{O}− are also coupled to the LC resonant circuit comprising inductor L 114, capacitor C 120, and varactors C_{A} 116 and C_{B} 118. The drain voltage of M3 106 and M4 108 are labeled as V_{D3} and V_{D4} respectively. Similarly, the gate voltage of M3 106 and M4 108 are labeled as V_{G3} and V_{G4} respectively. At zero differential voltage, both switching NMOS transistors M3 106 and M4 108 are in saturation, and the cross-coupled transconductance offers a small-signal negative differential conductance that induces startup of the oscillation. As the rising differential oscillation voltage crosses the threshold voltage of the NMOS device V_{T}, the V_{GD} of one NMOS transistor exceeds +V_{T}, forcing it into the linear region, and the V_{GD} of the other NMOS transistor falls below −V_{T}, driving it deeper into saturation or cut-off region. The output resistance of the NMOS transistor in linear region reduces with the differential voltage, and adds greater loss to the resonator. In the next half cycle, output resistance of the other NMOS transistor adds to the resonator loss. The two NMOS transistors lower the average resonator quality factor over a full oscillation cycle. Therefore, it is desirable to avoid the switching pair, i.e. M3 106 and M4 108, working in the linear region while maintaining large output voltage swing so as to achieve better phase noise performance. A current source I_{VCO} 112 is used to supply current for the VCO circuit.

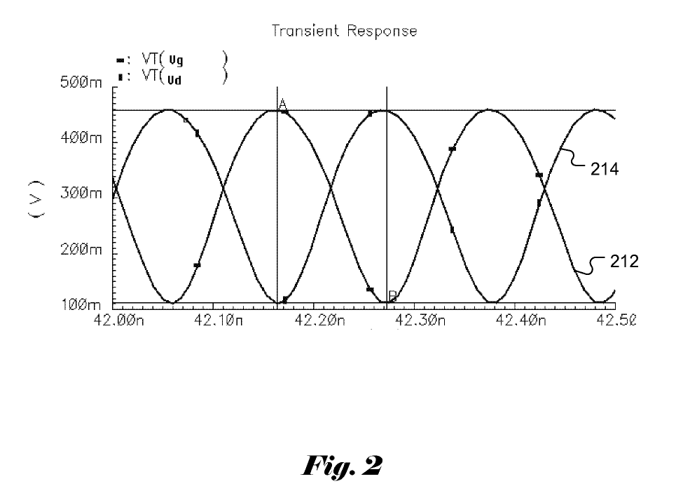

FIG. 2 illustrates the voltage waveforms at the drain and gate of the NMOS transistor. The waveforms for the two NMOS transistors are the same except for a nearly 180° phase difference between respective waveforms. Since the NMOS pair is directly cross-coupled, the gate voltage V_{G3} for M3 106 is the same as the drain voltage V_{D4} for M4 108. The waveforms shown in FIG. 2 are for both M3 106 and M4 108. In other words, the waveforms in FIG. 2 can represent the waveforms at gate and drain of M3 106. The waveforms in FIG. 2 may also represent the waveforms at gate and drain of M4 108 since the gate of M3 106 is connected to the drain of M4 108 and the gate of M4 108 is connected to the drain of M3 106. Furthermore, due to the direct cross-coupling, the waveforms in FIG. 2 also represent the waveforms of V_{D3} 212 and V_{D4} 214. The positive terminal V_{O+} of the output voltage is connected to the drain of M3 106 and the negative terminal V_{O-} of the output voltage is connected to the drain of M4 108. The differences between V_{O+} and V_{O-} represent the differential output of the VCO. Therefore, the difference between the two waveforms of FIG. 2 represents the differential output of the VCO. The voltage swing in FIG. 2 is maintained small enough so that V_{GD} of one NMOS transistor will not greater than +V_{T}. Therefore the NMOS pair will maintain in the saturation region for good phase noise. However, if the output voltage swing is increased exceeding the threshold voltage V_{T}, conventional VCO circuit of FIG. 1 will experience increased phase noise.

To overcome above issue with large VCO swing, noise filter is described in a publication by Hegazi, et al., entitled “A Filtering Technique to Lower LC Oscillator Phase Noise,” IEEE Journal of Solid-State Circuits, Vol. 36, No. 12, pp. 1921-1930, December 2001. According to Hegazi, et al., an LC noise filter is inserted at the common source point of the switching pair to resonate in parallel with the capacitance at that node. This method needs an additional inductor, which will increase chip cost noticeably if the additional inductor is integrated on chip. Furthermore, for a wide band LC VCO, the LC noise filter resonant frequency is difficult to change with VCO frequency. Therefore, the LC noise filter method by Hegazi, et al., is not suitable for application in the wide band LC VCO. The method and system described according to the present invention provides a solution for VCO having an LC resonant circuit and cross-coupled MOS pair with a large swing to reduce phase noise.

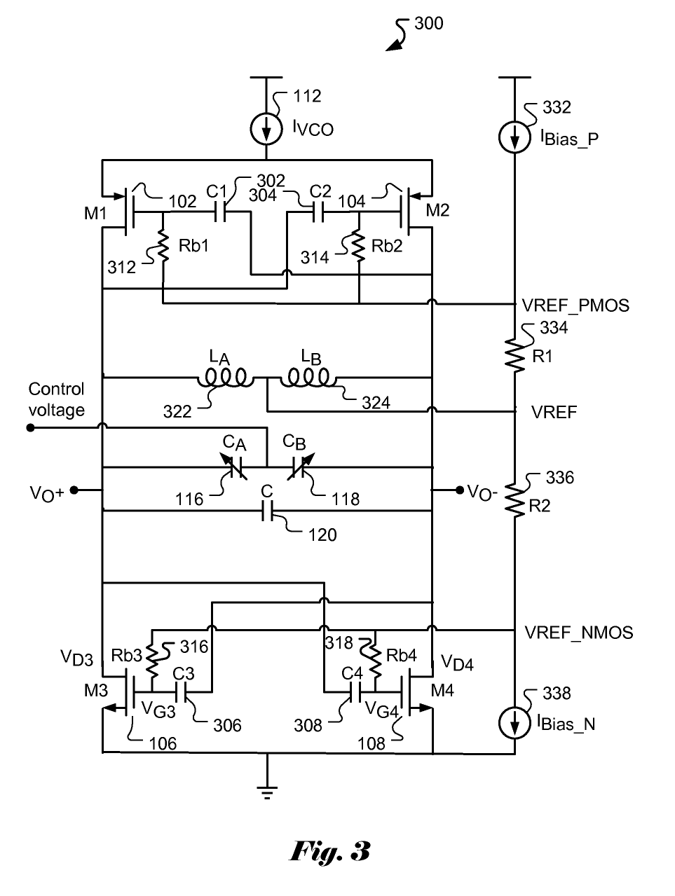

FIG. 3 illustrates a VCO circuit according to an embodiment of the present invention to overcome the increased phase noise issue associated with increased output voltage swing beyond the threshold voltage. Compared with the VCO circuit of FIG. 1, the system 300 of FIG. 3 uses AC cross-coupling, where each MOS pair is cross coupled through individual capacitors, C1 302, C2 304, C3 306 and C4 308. The capacitors, C1 302, C2 304, C3 306 and C4 308 are also called DC-blocking capacitors because they block DC coupling between the cross-coupled gate and drain. For the PMOS transistor pair, M1 102 and M2 104, a pair of capacitors, C1 302 and C2 304, is used to couple the drain signal of one PMOS transistor to the gate of the other PMOS transistor. A controllable bias voltage VREF_PMOS is supplied to the gates of the PMOS transistor pair through respective resistors Rb1 312 and Rb2 314. Similarly, for the NMOS pair M3 106 and M4 108, a pair of capacitors, C3 306 and C4 308, is used to couple the drain signal of one NMOS transistor to the gate of the other NMOS transistor. A controllable bias voltage VREF_NMOS is supplied to the gates of the NMOS transistor pair through respective resistors Rb3 316 and Rb4 318. Furthermore, a pair of inductors L_{A} 322 and L_{B} 324 is used to replace the original inductor L 114 of FIG. 1 so as to couple a common mode voltage VREF to the center tap of the pair of inductors L_{A} 322 and L_{B} 324 for the output voltage. For a same frequency tuning range, the total inductance of the inductance of inductors L_{A} 322 and L_{B} 324 is the same as the inductance of inductor L 114 of FIG. 1. Therefore, replacing a single inductor L 114 by a pair of inductors L_{A} 322 and L_{B} 324 will not increase the chip cost when the inductor is integrated into the chip.

Also illustrated in FIG. 3 is an exemplary circuit to supply the needed reference voltages VREF_PMOS, VREF_NMOS and VREF. A current source I_{Bias}_{_{—}}_{P} 332 along with a resistor R1 334 is used to generate a needed bias voltage for the PMOS pair. On the other hand, a current source I_{Bias}_{_{—}}_{N} 338 along with a resistor R2 336 is used to generate a needed bias voltage for the NMOS pair. As is known to a skill person in the field, there are many other ways to generate the needed bias voltages. The circuit and the method of generating bias voltages illustrated are shown for example and shall not be construed as limitations to the present invention.

Compared with the directly cross-coupled connection of switching pairs of FIG. 1, the use of the DC blocking capacitors C1 302 and C2 304 of FIG. 3 will allow the drain of transistor M2 104 to have different DC level from the gate of transistor M1 102. Similarly, the use of the DC blocking capacitors C3 306 and C4 308 of FIG. 3 will allow the drain of transistor M4 108 to have different DC level from the gate of transistor M3 106. As a result, the difference between the V_{D3} and V_{D4}, i.e., the differential output, does not have to be the same as the V_{GD} for M3 106 or M4 108 as in the direct cross-coupling arrangement of FIG. 1. Therefore, the output voltage swing of the VCO circuit of FIG. 3 is not restricted to V_{GD} for both MOS pairs to be operated in saturation mode.

In FIG. 3, the two inductors L_{A} 322 and L_{B} 324 can be implemented as two single ended standard inductors or one symmetry inductor with center tap. The middle point of the two standard inductors is also called center tap for simplicity. The switching pair bias network comprises current sources, I_{Bias}_{_{—}}_{P} 332 and I_{Bias}_{_{—}}_{N} 338, voltage shifting elements, R1 334 and R2 336, isolation resistors, Rb1 312, Rb2 314, Rb3 316, and Rb4 318, and a reference voltage VREF. The voltage shifting elements can also be implemented in MOS transistors or other devices that can shift a voltage level from the reference voltage VREF. The current sources, I_{Bias}_{_{—}}_{P} 332 and I_{Bias}_{_{—}}_{N} 338, have the same value in this example. However, other arrangement may also be used to provide the needed reference voltages. The reference voltages generated by the bias generation circuit of FIG. 3 are described as follows. Both the outputs of current sources I_{Bias}_{_{—}}_{P} 332 and I_{Bias}_{_{—}}_{N} 338 are high impedance circuits. The output voltage of I_{Bias}_{_{—}}_{N} 338 can be calculated as VREF_NMOS=VREF −I_{Bias}_{_{—}}_{N}·R2 and, the output voltage of I_{Bias}_{_{—}}_{P} 332 can be calculated as VREF_PMOS=VREF+I_{Bias}_{_{—}}_{P}·R1. VREF_NMOS is coupled to the NMOS switching pair through two isolation resistors Rb3 316 and Rb4 318 wherein the values of Rb3 316 and Rb4 318 should be large enough to isolate the M3 and M4 gates. VREF_PMOS is coupled to the PMOS switching pair through two isolation resistors Rb1 312 and Rb2 314 wherein the values of Rb1 312 and Rb2 314 should be large enough to isolate the M1 and M2 gates. In the example of FIG. 3, the VREF is connected to the inductor center tap and the DC voltage of the inductor center tap is the drain voltage of the switching pairs (PMOS and NMOS). The DC level of the gate voltage of the PMOS switching pair is I_{Bias}_{_{—}}_{P}·R1 higher than the DC level of the drain voltage of the PMOS switching pair. Similarly, the DC level of the gate voltage of the NMOS switching pair is I_{Bias}_{_{—}}_{N}·R2 lower than the DC level of the drain voltage of the NMOS switching pair.

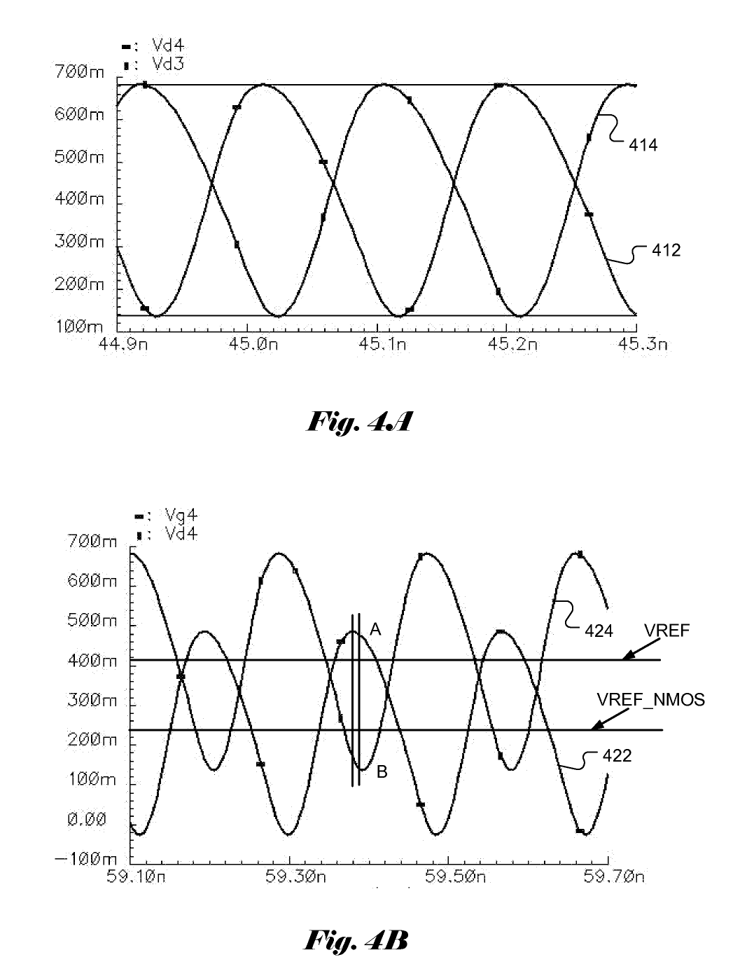

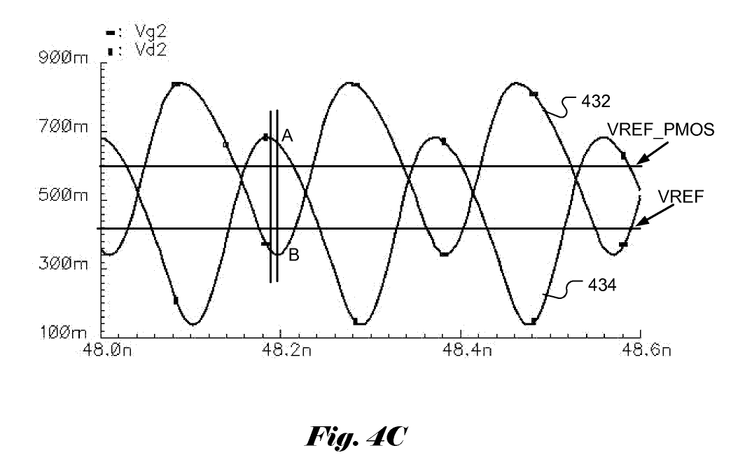

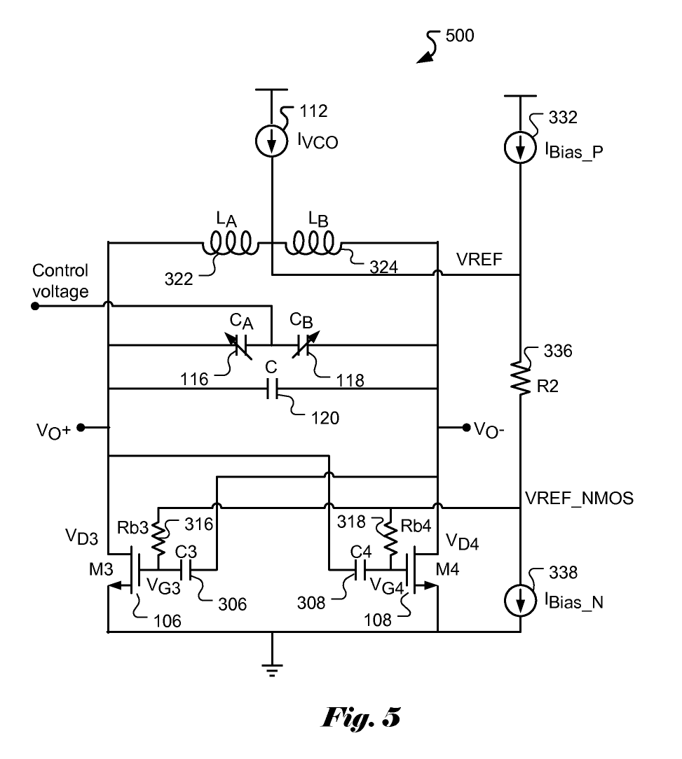

For the VCO circuit of FIG. 3, both switching NMOS transistors are in saturation at zero differential NMOS drain voltage, and NMOS drain voltage is I_{Bias}_{_{—}}_{N}·R2 higher than the NMOS gate voltage. Therefore, as long as the drain voltage of the NMOS transistor does not rises beyond V_{T}+I_{Bias}_{_{—}}_{N}·R2, the V_{GD} of the associated NMOS transistor will not exceed +V_{T} so as to remain in the saturation region. On the other hand, the V_{GD} of the other NMOS transistor may remains further below −V_{T}−I_{Bias}_{_{—}}_{N}−R2 driving it deeper into saturation. FIG. 4A illustrates an exemplary drain voltage outputs having increased voltage swing. The differential output is derived based on the difference between the two drain output waveforms. Accordingly, the increased drain output swing of M3 106 412 and M4 108 414 will result in increased differential output swing. While providing increased output swing, the system illustrated in FIG. 3 will not suffer from the potential increase in phase noise because the transistors M3 106 and M4 108 still stay in the saturated region with increased output swing. FIG. 4B illustrates the drain voltage and gate voltage corresponding to transistor M4 108. The gate to drain voltage V_{GD} for transistor M4 108 is calculated by subtracting the drain voltage from the gate voltage for each corresponding time instance. The maximum positive V_{GD} value is labeled as A and B in FIG. 4B, which is about the same value as that in FIG. 2 where the output swing is smaller than that in FIG. 4A. On the other hand, the maximum magnitude of the negative V_{GD} value is even larger than that for a conventional VCO circuit. Nevertheless, the further negative V_{GD} value will push the NMOS transistor into saturation region or cut-off region and will not cause degradation in phase noise. Because the drain voltage and gate voltage can be independently offset as illustrated in FIG. 4B, the VCO circuit of FIG. 3 can provide increased output swing without causing any of the NMOS transistors into the linear region. As shown in FIG. 4B, the DC value of the gate voltage for transistor M4 108 is associated with VREF_NMOS while the DC value of the drain voltage for transistor M4 108 is associated with VREF. Since the reference voltage arrange always causes VREF_NMOS lower than VREF, the effect of reference voltages VREF_NMOS and VREF will shift the gate voltage waveform 422 downward with respect to the drain voltage waveform 424. As a result, the reference voltage arrangement can reduce the maximum gate-to-drain voltage V_{GD} appearing on transistors M3 106 and M4 108. The advantages of the embodiment according to the present invention of using AC cross-coupling and supplying a proper reference voltage to the transistor pair can be easily illustrated by the gate and drain waveforms of the transistor pair. The maximum gate-to-drain voltage V_{GD} for transistors M3 106 and transistor M4 108 is maintained to be small even though the amplitude is increased. Similarly, the VCO circuit of FIG. 3 will also keep the PMOS pair in the saturation region while keeping the NMOS pair in the saturation region as shown in FIG. 4C. As shown in FIG. 4C, the DC value of the gate voltage for transistor M2 104 is associated with VREF_PMOS while the DC value of the drain voltage for transistor M2 104 is associated with VREF. Since the reference voltage arrange always causes VREF_PMOS to be higher than VREF, the effect of applying reference voltages VREF_PMOS and VREF to the PMOS transistor pair will shift the gate voltage waveform 432 upward with respect to the drain voltage waveform 434. As a result, the reference voltage arrangement can reduce the maximum drain-to-gate voltage V_{DG} appearing on transistors M1 102 and M2 104. It is preferred to select the reference voltages, VREF_NMOS, VREF, and VREF_PMOS properly so that (VREF_PMOS−VREF)+|VT_{PMOS}|=(VREF-VREF_NMOS)+|VT_{NMOS}, where VT_{PMOS} is the threshold voltage for the PMOS transistor and VT_{NMOS} is the threshold voltage for the NMOS transistor. Typically, the NMOS and PMOS transistors have about the same threshold voltage magnitude, therefore the bias voltages can be chosen to satisfy VREF_PMOS−VREF=VREF−VREF_NMOS.

FIG. 5 illustrates a VCO circuit according to another embodiment of the present invention. While the negative impedance element of the VCO circuit in FIG. 3 comprises a PMOS transistor pair and an NMOS transistor pair, the negative impedance element of the VCO circuit 500 in FIG. 5 comprises an NMOS transistor pair. The VCO circuit 500 is also referred to as NMOS-only topology in the field and it usually results in higher phase noise compared with the VCO circuit having complementary MOS pairs with the same power. As described previously for the circuit in FIG. 3, the AC-coupling capacitors, C3 306 and C4 308, and the reference voltages, VREF and VREF_NMOS, can cause the gate voltage waveform and the drain voltage waveform to shift as shown in FIG. 4B. Consequently, the maximum gate-to-drain voltage V_{GD} for transistors M3 106 and M4 108 remains to be small while the amplitude is increased.

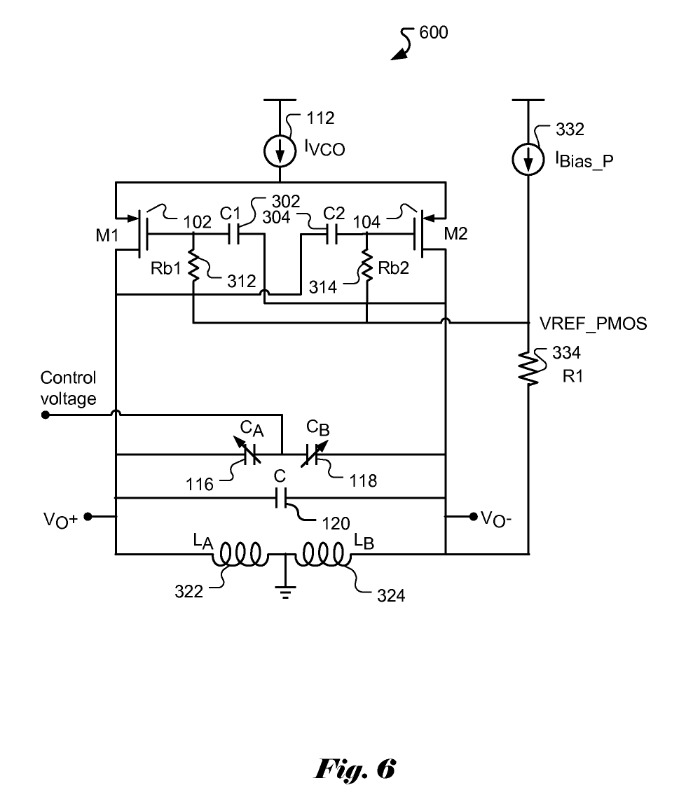

FIG. 6 illustrates a VCO circuit according to another embodiment of the present invention. While the negative impedance element of the VCO circuit in FIG. 3 comprises a PMOS pair and an NMOS pair, the negative impedance element of the VCO circuit 600 in FIG. 6 comprises an NMOS transistor pair. The VCO circuit 600 is also referred to as PMOS-only topology in the field and it usually results in higher phase noise compared with the VCO circuit having complementary MOS pairs. As described previously for the circuit in FIG. 3, the AC-coupling capacitors, C1 302 and C2 304, and the reference voltages, VREF and VREF_PMOS, can cause the gate voltage waveform and the drain voltage waveform to shift as shown in FIG. 4C. Consequently, the maximum drain-to-gate voltage V_{DG} for transistors M1 102 and M2 104 remains to be small while the amplitude is increased.

The invention may be embodied in other specific forms without departing from its spirit or essential characteristics. The described examples are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. A voltage controlled oscillator (VCO) circuit having extended output voltage swing comprising:
an LC resonant circuit comprising an inductive element and a capacitive element, wherein the capacitive element has a capacitance value controlled by a control voltage;
a negative impedance element comprising one or more cross-coupled transistor pairs, wherein each of said one or more cross-coupled transistor pairs comprises a first transistor and a second transistor, wherein first transistor gate is coupled to second transistor drain and second transistor gate is coupled to first transistor drain; and
an output swing extension circuit, wherein the output swing extension circuit causes the first transistor gate to be AC-coupled to the second transistor drain and the second transistor gate to be AC-coupled to the first transistor drain, and wherein the output swing extension circuit provides bias voltages to the LC resonant circuit and the negative impedance element to extend the output voltage swing while maintaining the cross-coupled transistors in a saturation region.

2. The voltage controlled oscillator (VCO) circuit of claim 1, wherein said one or more cross-coupled transistor pairs is a cross-coupled NMOS transistor pair.

3. The voltage controlled oscillator (VCO) circuit of claim 2, wherein the output swing extension circuit is configured to cause a gate DC level at the first transistor gate and the second transistor gate lower than a drain DC level at the first transistor drain and the second transistor drain respectively.

4. The voltage controlled oscillator (VCO) circuit of claim 1, wherein said one or more cross-coupled transistor pairs is a cross-coupled PMOS transistor pair.

5. The voltage controlled oscillator (VCO) circuit of claim 4, wherein the output swing extension circuit is configured to cause a gate DC level at the first transistor gate and the second transistor gate higher than a drain DC level at the first transistor drain and the second transistor drain respectively.

6. The voltage controlled oscillator (VCO) circuit of claim 1, wherein said one or more cross-coupled transistor pairs comprises one cross-coupled NMOS transistor pair and one cross-coupled PMOS transistor pair.

7. The voltage controlled oscillator (VCO) circuit of claim 6, wherein the output swing extension circuit is configured to cause a first gate DC level at the first transistor gate and the second transistor gate of the cross-coupled NMOS transistor pair lower than a first drain DC level at the first transistor drain and the second transistor drain of the cross-coupled NMOS transistor pair respectively, and wherein the output swing extension circuit is configured to cause a second gate DC level at the first transistor gate and the second transistor gate of the cross-coupled PMOS transistor pair higher than a second drain DC level at the first transistor drain and the second transistor drain of the cross-coupled PMOS transistor pair respectively.

8. The voltage controlled oscillator (VCO) circuit of claim 1, wherein the output swing extension circuit comprises one or more current sources and one or more impedance devices, wherein said one or more current sources and said one or more impedance devices are configured to provide the bias voltages.

9. The voltage controlled oscillator (VCO) circuit of claim 1, wherein the inductive element includes a center tap to receive one of the bias voltages provided by the output swing extension circuit.

10. A method for extending output voltage swing for a voltage controlled oscillator (VCO) circuit comprising an LC resonant circuit having an inductor with a center tap, and a negative impedance element having one or more cross-coupled transistor pairs, the method comprising:
proving a DC-blocking device for said one or more cross-coupled transistor pairs, wherein the DC-blocking device is configured to cause DC level blocked between cross-couple gate and drain of said one or more cross-coupled transistor pairs;
providing a first bias voltage to the center tap of the inductor; and
providing one or more second bias voltages to cross-coupled gates of said one or more cross-coupled transistor pairs respectively, wherein the first bias voltage and said one or more second bias voltages are configured to maintain said one or more cross-coupled transistor pairs in a saturation region when output voltage of the VCO circuit is increased.

11. The method of claim 10, wherein said one or more cross-coupled transistor pairs is a cross-coupled NMOS transistor pair, and the first bias voltage and said one or more second bias voltages cause a gate DC level at the cross-coupled gates lower than a drain DC level at drains of said one or more cross-coupled transistor pairs.

12. The method of claim 10, wherein said one or more cross-coupled transistor pairs is a cross-coupled PMOS transistor pair, and the first bias voltage and said one or more second bias voltages cause a gate DC level at the cross-coupled gates higher than a drain DC level at drains of said one or more cross-coupled transistor pairs.

13. The method of claim 10, wherein the DC-blocking device comprises a capacitor to block the DC level.

14. The method of claim 10, wherein said one or more second bias voltages are provided using one or more current sources and one or more impedance devices.
